(19) United States
(12) Patent Application Publication
(10) Pub. No.: US 2013/0271113 A1
(43) Pub. Date: Oct. 17, 2013

(54) Diffractive MEMS based fiber optic AC electric field strength/voltage sensor for applications in high voltage environments

(71) Applicants: Xuekang SHAN, San Diego, CA (US); Jin Hao, San Diego, CA (US)

(72) Inventors: Xuekang SHAN, San Diego, CA (US); Jin Hao, San Diego, CA (US)

(21) Appl. No.: 13/449,305

(22) Filed: Apr. 17, 2012

(51) Int. Cl. G01R 19/00

(52) U.S. Cl. 324/96

(57) ABSTRACT

A fiber optic AC electric field or voltage sensing system is described for applications in high voltage environment, particularly, in the vicinity of a power line. The system is based on diffractive MEMS device. A condenser antenna positioned in the electric field feeds a voltage signal to the diffractive MEMS device, which then modulates the light signal passing through it. In the optical receiver, the electric filed strength is measured from the received optical signal.

The present invention relates generally to optical sensors, and more particularly, to the type of optical sensors that respond to an electric field or voltage, and systems which include such sensors for electric field/voltage measurements.

Cited Patent

1. GB2400172, UK patent X. Shan and H. Li

### BACKGROUND OF THE INVENTION

In the high voltage (HV) industry, electric current and voltage measurement is essential yet difficult. Insulation in traditional current transformers and voltage transformers is always a concern, and as a result, these transformers are expensive and bulky. In HV system maintenance, portable electric current and voltage measurement equipment is highly desirable. However, due to the bulkiness, traditional current/voltage transformers for HV applications can not be made portable.

In recent years, fiber optic sensors have been invented and developed. Because optical fibers are intrinsically good insulators, fiber optic sensors are automatically suitable for use in HV environments. In particular, fiber optic current sensors and voltage/electric field strength sensors have been developed and are being used in HV industry. Their advantages over traditional current/voltage transformers include:

1. Good insulation ensures the safety of operating personnel;

2. No need for oil or SF6 gas for insulation;

3. Electro-magnetic interference immunity.

4. It is possible to make these sensors portable.

At present, most fiber optic electric field sensors utilize optical polarization rotation effect in electro-optic crystals, most commonly, Pockels cell, or lithium niobate crystal.

A typical electric field sensor based on lithium niobate crystal consists of a light source, two optical fibers, a polarizer, and a piece of lithium niobate crystal with an optical waveguide in it, and polarization beam splitter.

A light source launches optical power into an optical fiber, which guides light into a polarizer. After the polarizer the light becomes linearly polarized before entering the lithium niobate waveguide device. A dipole antenna picks up the electric filed and converts it into a voltage. This voltage is applied to the electrodes on the waveguide device, and causes the devices to induce a polarization rotation of the light that passes through it. A polarization beam splitter separates the two orthogonal polarization states which are then received by respective optical receivers. From the received signals, the voltage applied to the lithium niobate waveguide device can be calculated, and then the electric field strength can be determined.

Such electric field strength sensors are based on the polarization rotation effects in the electro-optic crystals. However, polarization properties of electro-optic crystals are affected by many factors other than the applied voltage to the crystal, such as strain, temperature, aging, etc. To make electric field strength sensors with high accuracy and reliability is still a challenge.

### DESCRIPTION OF THE INVENTION

The present invention describes a new method of fiber optic measurement of electric field strength in high voltage environments by utilizing Diffractive Micro Electro Mechanical Systems (MEMS) devices.

Diffractive MEMS devices are widely used in optical communications equipment. In one form, these devices work as variable optical attenuators (VOAs). When a voltage is applied to the device, its optical attenuation changes, and therefore, it controls the amount of light that passes through it when the input light level is kept constant. Some useful characteristics of this type of VOA are i. its speed of responding to the applied voltage is fast, on the order of tens of microseconds, fast enough for 50/60 Hz signal; ii. It is not sensitive to the polarization of the input light; iii. It is not sensitive to mechanical vibration; iv. It is a voltage driven device and draws almost no current, so that it can be used to detect electric field; iv. It is extremely durable with a wear out life of more than 100 billion cycles, as against 10 million for normal MEMS VOAs. When working at 50/60 Hz, this wear out life means over 50 years of continuous operation.

A prior art (1) described an optical AC current sensor using Diffractive MEMS devices. An air core coil is mounted around current carrying conductor which converts the alternating magnetic field into an AC voltage. This AC voltage then drives the Diffractive MEMS device, and the optical signal passing through this device is thus being modulated. At the optical receiver, this modulated optical signal is converted into electrical signal, and thus the AC current in the conductor is measured.

The present invention proposes a new method and apparatus to measure AC electric field intensity/voltage in high voltage environments based on diffractive MEMS device. This electric field strength/voltage measurement system consists of a light source, a diffractive MEMS based sensor head, an optical receiver, and optical fibers that connect the light source to the sensor head, and the sensor head to the optical receiver. The light source sends a stable optical power to the sensor head. The diffractive MEMS device in the sensor head is connected to a condenser antenna which is exposed to AC electric field and converts this field to a voltage. This voltage drives the diffractive MEMS device, and the optical signal passing through the diffractive MEMS device is thus being modulated. The optical receiver converts the optical signal into an electric signal, and the AC electric field is measured.

In another application, the diffractive MEMS based sensor head is connected to a voltage divider, which is connected to an AC voltage. This AC voltage is measured from the output of the optical receiver. This voltage divider can bed either resistive, or capacitive.

### BRIEF DESCRIPTION OF THE DRAWINGS

FIG. 1 shows a typical optical attenuation vs applied voltage curve for diffractive MEMS VOA.

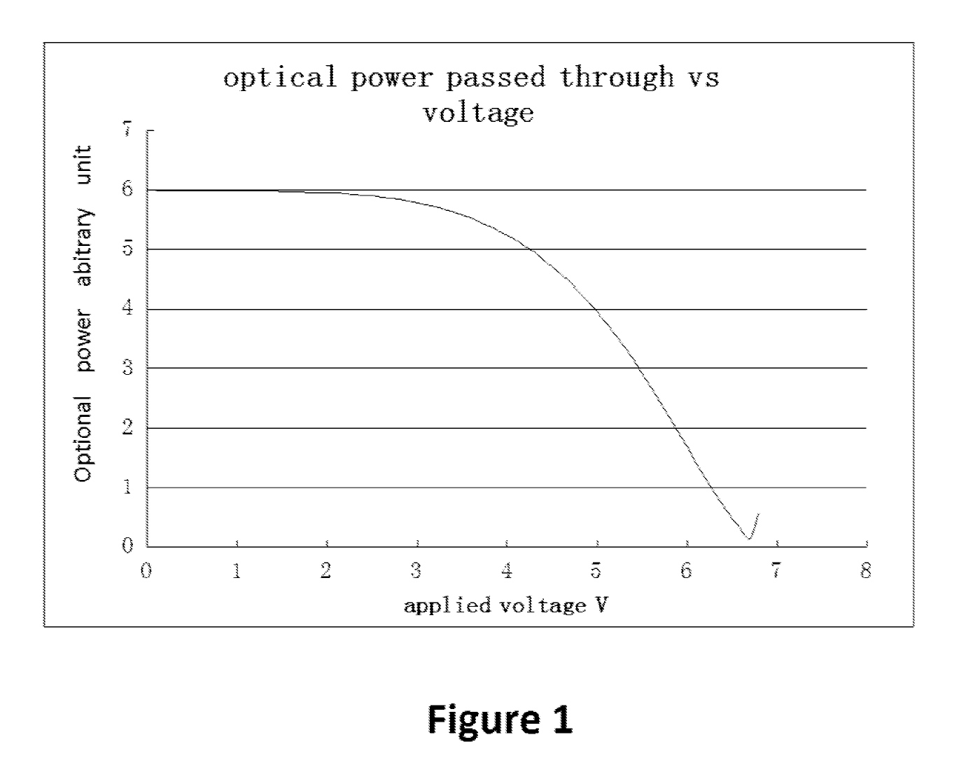

FIG. 2 shows a First Preferred Embodiment of diffractive MEMS VOA based AC electric field strength sensor.

FIG. 3 shows second preferred embodiment of diffractive MEMS VOA based AC electric field strength sensor with a DC bias for the diffractive MEMS VOA.

FIG. 4 shows third preferred embodiment of diffractive MEMS based AC voltage sensor employing resistive voltage divider.

FIG. 5 shows fourth preferred embodiment of diffractive MEMS based AC voltage sensor employing capacitive voltage divider.

### DETAILED DESCRIPTION OF THE PREFERRED EMBODIMENTS

This invention describes a new method to measure electric field strength or voltage in a HV environment by a fiber coupled diffractive MEMS device. Compared to prior art in which electro optic crystals are used to generate light signal polarization rotation, this invention provides a simpler and more cost effective solution. In one form, the diffractive MEMS device is built as a variable optical attenuator VOA, which changes the attenuation to the optical signal passing through it when a voltage is applied to it. This type of VOA responds to the applied voltage within a few tens of micro seconds, has a high electric impedance to driving voltage, and has a low driving voltage of no more than 6 volts to generate a 30 dB optical attenuation. These characteristics make this type of VOA respond to AC with frequencies up to 1 kHz.

The diffractive MEMS VOA can be connected to a dipole/condenser antenna to form an fiber optic AC electric field strength sensor. The diffractive MEMS VOA can also be connected to a capacitive or resistive voltage divider to form an fiber optic AC voltage sensor.

### First Preferred Embodiment

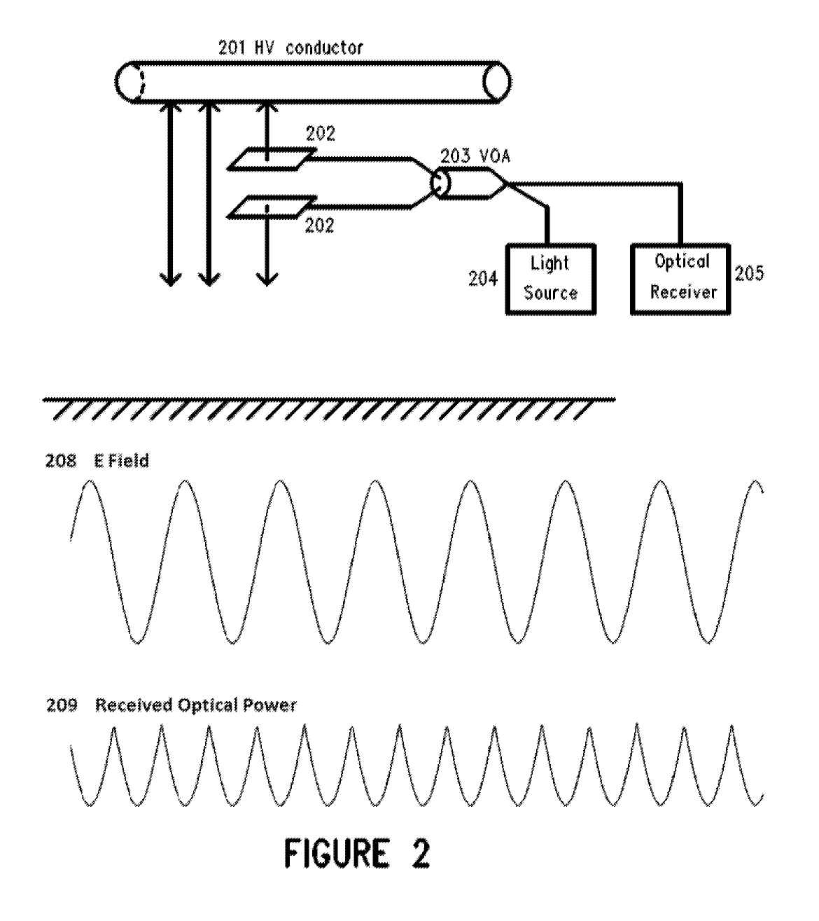

As is shown in FIG. 2, in a first embodiment, the VOA 203 is connected to a condenser antenna 202 without a DC biasing voltage. The VOA works at zero DC bias, and its optical modulation is not linear to the AC driving voltage. FIG. 2 shows the output electric signal from the optical receiver 205. Because there is no DC bias for the VOA, the output electric signal 209 has a repetition frequency twice that of the driving AC voltage 208.

### Second Preferred Embodiment

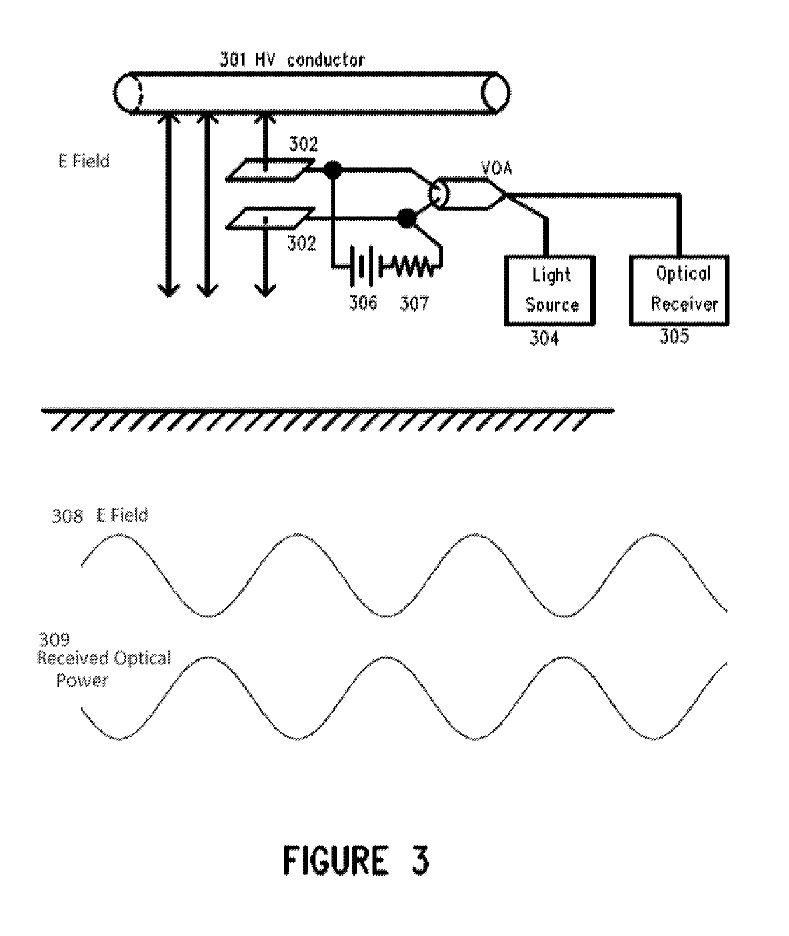

As is shown in FIG. 3, in a second embodiment, the diffractive MEMES VOA 303 is used to measure AC electric filed. The VOA is biased with a DC voltage 306 of a few volts, via a resistor 307 (normally of the order of mega ohm). A condenser antenna 302 is connected to the VOA, as is shown in FIG. 3 The DC voltage sets the VOA working point such that its optical modulation depth is most linear against driving voltage. The condenser antenna converts the AC electric filed into an AC voltage, which then drives the VOA. The light signal that passes through the VOA is thus being modulated by the AC voltage. This modulated light signal is then received by an optical receiver 305, which converts the optical signal into an electric signal. FIG. 3 shows the output electrical signal 309, which is proportional to the electric field intensity 308 being measured.

### Third Preferred Embodiment

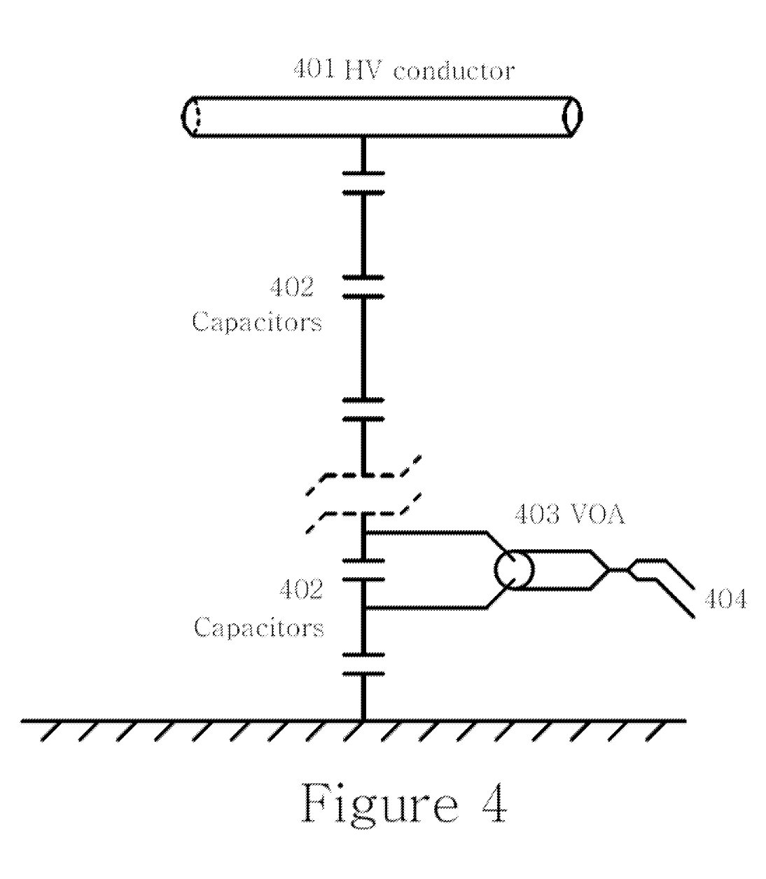

As is shown in FIG. 4, in a third embodiment, the VOA 404 is connected to a capacitive voltage divider 402, and the voltage divider is connected to an AC HV conductor 401. The divider provides a low AC voltage to drive the VOA, and from the optical output of the VOA the AC voltage on the HV conductor is measured.

### Fourth Preferred Embodiment

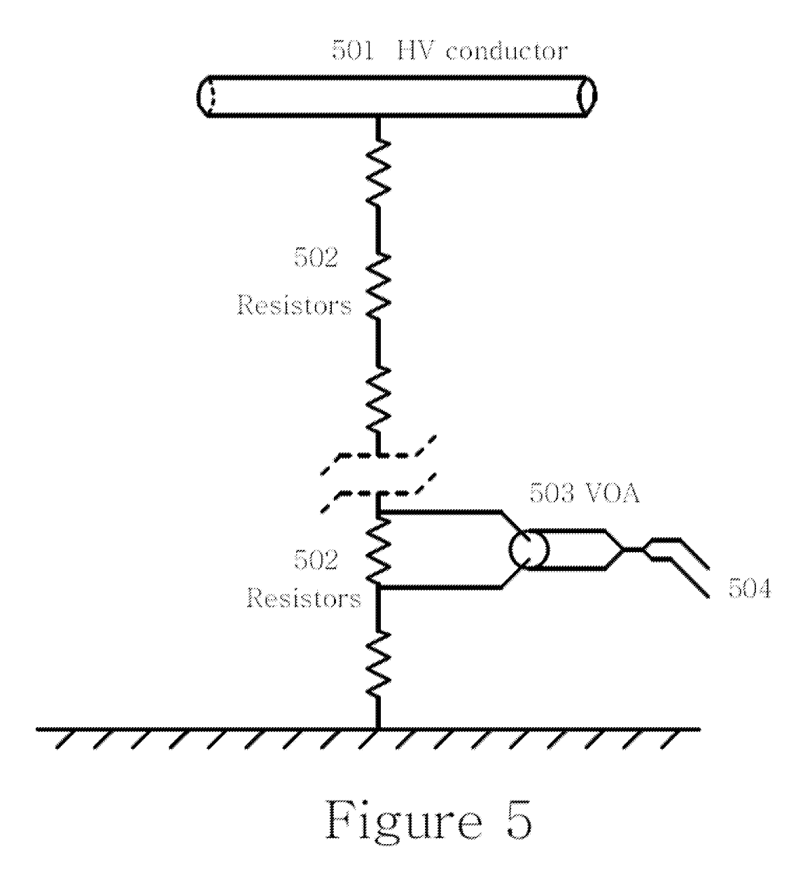

As is shown in FIG. 5, in a fourth embodiment, the VOA 504 is connected to a resistive voltage divider 502, and the voltage divider is connected to a HV conductor 501. The divider provides a low AC voltage to drive the VOA, and from the optical output of the VOA the AC voltage on the HV conductor is measured.

What is claimed is:

1. A Diffractive Micro-Electro-Mechanical System (MEMS) Variable Optical Attenuator (VOA) based optical AC electric field strength or voltage sensor for detecting an AC electric field intensity or voltage in high voltage environments comprising:
a. A light source with a stable continuous wave output;
b. A condenser antenna converting AC electric field to an AC voltage signal;
c. A diffractive MEMS device connected to said condenser antenna and modulating input continuous wave optical signal;
d. An optical receiver converting received optical signal into electrical signal;

2. An optical AC electric field strength sensor according to claim 1 has an electrical circuit
a. that combines a DC bias voltage and said AC voltage signal from said condenser antenna;
b. that feeds electric signal to said diffractive MEMS VOA.
c. that comprises temperature sensitive resistor(s), to compensate the temperature drift of modulation depth of said diffractive MEMS VOA as in claim 1;

3. A Diffractive Micro-Electro-Mechanical System (MEMS) Variable Optical Attenuator (VOA) Based optical AC voltage sensor comprising:
a. A light source with a stable continuous wave output;
b. A voltage divider providing a reduced AC voltage;
c. A diffractive MEMS device connected to a voltage divider and modulating input continuous wave optical signal;
d. An optical receiver converting received optical signal into electrical signal;

4. A voltage divider according to claim 3c is a resistive voltage divider or a capacitive voltage divider.
